(19) United States
(12) Patent Application Publication
(10) Pub. No.: US 2018/0109069 A1
(43) Pub. Date: Apr. 19, 2018

(54) METHOD FOR SCANNING WAVELENGTH OF EXTERNAL CAVITY LASER

(71) Applicant: Mark C. Phillips, Kennewick, WA (US)

(72) Inventor: Mark C. Phillips, Kennewick, WA (US)

(21) Appl. No.: 15/782,659

(22) Filed: Oct. 12, 2017

Related U.S. Application Data
(60) Provisional application No. 62/407,929, filed on Oct. 13, 2016.

(51) Int. Cl. H01S 3/139; H01S 5/14; H01S 5/065; H01S 5/0683; H01S 3/13

(52) U.S. Cl. CPC H01S 3/139; H01S 5/143; H01S 3/1305; H01S 5/0683; H01S 5/0653

(57) ABSTRACT

A system and method for scanning the wavelength of an external cavity laser uses synchronized angular motions of two mirrors. By adjusting the angular motions in a selected ratio, it is possible to change the lasing wavelength of the cavity without mode-hops. The mode-hop free ratio of angular motions is determined by simultaneously satisfying the conditions of wavelength selected by diffraction angle from a diffraction grating, and the length of the external cavity.

### CROSS-REFERENCE TO RELATED APPLICATIONS

This is a non-provisional application that claims the benefit of U.S. Provisional Patent Application No. 62/407,929, filed Oct. 13, 2016, which is incorporated by reference in its entirety herein.

### ACKNOWLEDGMENT OF GOVERNMENT SUPPORT

This invention was made with government support under Contract DE-AC0576RL01830 awarded by the U.S. Department of Energy. The government has certain rights in the invention.

### FIELD

The field is tunable external cavity lasers.

### BACKGROUND

A typical external cavity laser consists of a gain medium, an angle-based wavelength selection element such as a diffraction grating, and a retro-reflecting element to complete the laser cavity. However, conventional external cavity lasers, including those in Littrow or Littman-Metcalf configurations, are prone to mode-hopping. For many applications, including applications in spectroscopy and sensing requiring high spectral resolution, mode-hops can cause significant problems. Also, industrial applications of rapidly-swept external cavity lasers include gas sensing for chemical detection or process monitoring, including in-situ combustion monitoring, and current commercially available approaches to tuning of external cavity lasers are either too slow, or do not have sufficient spectral resolution, for high-performance sensing applications. Furthermore, a need exists to adjust the wavelength of an external cavity quantum cascade laser, including over >1 cm⁻¹ ranges and/or at rates>1 kHz and existing approaches are unsuitable or undesirable for meeting the needs. Examples of the disclosed technology described herein solve these problems and meet these needs. Additional advantages and novel features are set forth as follows and will be readily apparent from the descriptions and demonstrations herein.

### SUMMARY

Apparatus, systems, and methods for scanning the wavelength of an external cavity laser using synchronized angular motions of two mirrors are disclosed. According to some examples of the disclosed technology, apparatus include a first reflector rotatable about a first axis and situated to receive an intracavity laser beam of an external cavity laser from a diffraction grating and to direct the intracavity laser beam along a first direction, and a second reflector rotatable about a second axis and situated to retro-reflect the intracavity laser beam received from the first reflector back to the first reflector and to the diffraction grating.

According to additional examples of the disclosed technology, systems include a plurality of reflectors of an external cavity laser, each situated to rotate about respective axes in relation to a diffraction grating and laser source situated in a fixed relation to each other, at least one processor, and one or more computer-readable storage media including stored instructions that, responsive to execution by the at least one processor, cause the system to rotate the plurality of reflectors so as to vary an external cavity length and an external cavity output beam wavelength.

According to further examples of the disclosed technology, methods include directing an intracavity laser beam produced by a laser source to a diffraction grating, directing a first portion of the intracavity laser beam received by the diffraction grating along an output direction so as to form an output beam of an external cavity laser, and directing a second portion of the intracavity laser beam received by the diffraction grating to a first reflector rotatable about a first axis and to a second reflector rotatable about a second axis so as to retro-direct the second portion back to the first reflector, diffraction grating, and laser source, wherein the first reflector and second reflector are situated to independently rotate about respective axes so as to vary a wavelength of the output beam.

According to additional examples of the disclosed technology, methods include selecting an external cavity output beam wavelength of an external cavity laser that includes a diffraction grating and a laser source situated in a fixed relation to each other, and rotating an intracavity first reflector and an intracavity second reflector so as to vary a wavelength of the output beam and a length of the external cavity of the external cavity laser.

The foregoing and other advantages of the disclosed technology will become more apparent from the following detailed description, which proceeds with reference to the accompanying figures.

### BRIEF DESCRIPTION OF THE DRAWINGS

FIG. 1 is a schematic of an example of an external cavity laser.

FIGS. 2A-2B show schematics of additional example external cavity lasers.

FIG. 3 shows a geometric model of a cavity of an external cavity laser showing a beam path and intersections with the tuning mirrors.

FIGS. 4A-4D show calculated angle of a second mirror and laser wavenumber as a function of angle of a first mirror for different values of a scale parameter k between the first mirror and the second mirror.

FIG. 5 is a graph of optimized scan angle of a second mirror for a linear scan of a first mirror angle.

FIG. 6 is a graph scanning results of an example external cavity laser with mode-hop free operation.

FIGS. 7A-7C are graphs of wavelength tuning behavior for an external cavity laser example.

FIG. 8 is a schematic of an example of an external cavity laser system.

FIG. 9 is a flowchart of an example method of varying a wavelength of an external cavity laser.

FIG. 10 is a flowchart of an example method of scanning a wavelength of an external cavity laser.

### DETAILED DESCRIPTION

The following description includes the various embodiments of the present disclosed technology. It will be clear from this description that the disclosed technology is not limited to these illustrated embodiments but also includes a variety of modifications thereto including combinations of features from different embodiments.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

As used herein, beams refer to laser light that includes electromagnetic radiation at wavelengths of between about 100 nm and 1000 μm. Various laser source examples herein include semiconductor gain media, such as quantum cascade lasers, diode lasers, and other media. In various embodiments, optical components, such as lenses, diffractive elements (e.g., diffraction gratings), reflective elements (e.g., mirrors), mounts, housings, etc., are used.

Tunable external cavity lasers, using diode laser or quantum cascade lasers as gain media, are difficult to scan in wavelength without discontinuities in wavelength and power caused by mode-hops. The lasing wavelength is determined by the angular position of the elements, in combination with the lasing cavity length which must be an integral number of half-wavelengths. Mode-hops arise when the cavity elements are adjusted asynchronously, so that the wavelength change selected by the angle does not match the wavelength change selected by the cavity length. When the wavelength change selected by the angle differs from the cavity length change by a nominal half wavelength, the lasing wavelength will “hop” to the adjacent external cavity mode, causing a discontinuity in wavelength and output optical power.

Some approaches directed at reducing or eliminating mode-hops use an additional tuning element to adjust the cavity length separately from the feedback angle. Examples include using a linear adjustment of the end mirror to compensate for the angular motion, or inclusion of a tilting etalon inside the cavity. For quantum cascade lasers in the infrared spectral region, the long wavelength can make use of linear adjustments difficult due to the large linear motions required. Another approach involves selecting the pivot point of the angular tuning element precisely so that the cavity length is adjusted in the correct ratio to the cavity length. However, the pivot point is located some distance away from the tuning elements themselves, and the pivot point must be located with extremely high mechanical tolerances. These factors make rapid tuning over large wavelength ranges difficult, if not impossible.

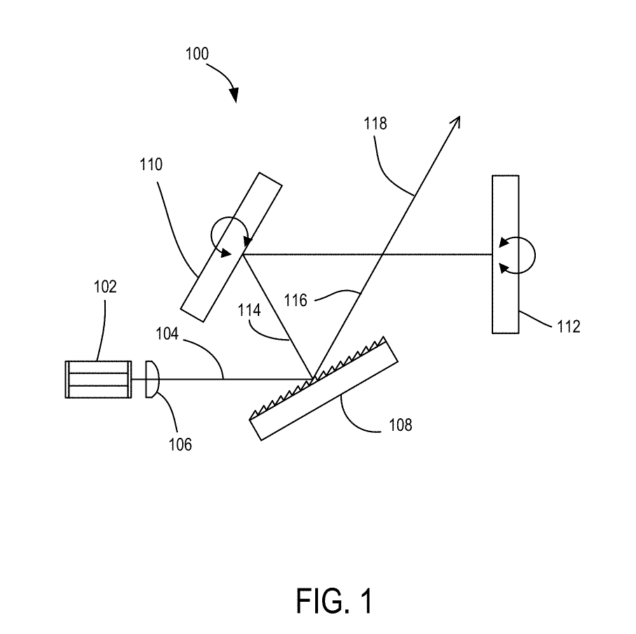

FIG. 1 shows an example of an external cavity laser 100 that is generally distinct from traditional Littman-Metcalf configurations, and in some examples can be considered to be a modified Littman-Metcalf configuration. The external cavity laser 100 includes a laser 102, such as a quantum cascade laser (QCL), interband cascade laser (ICL), or diode laser, by way of example, situated to produce a laser beam 104. The laser beam 104 is typically collimated with one or more lens components 106 and is directed to a diffraction grating 108. First and second mirrors 110, 112 are situated to reflect a first beam portion 114 of the laser beam 104 that is received as a diffracted beam from the diffraction grating 108 so as to provide optical feedback to the laser 102. A second beam portion 116 is diffracted by the diffraction grating 108 as an output beam 118 of the external cavity laser 100. The first and second mirrors 110, 112 are independently rotatable so as to vary feedback angle and cavity length of the external cavity laser 100. In typical examples, the rotations of the first and second mirrors 110, 112 are selected so that the variation of the feedback angle and cavity length provide wavelength tuning of the laser 102 without frequency discontinuities or mode-hops. In some examples, the rotation angles of the first and second mirrors 110, 112 are adjustable in selected ratios that provide wavelength tuning without mode-hops over a wavenumber range of greater than about 1 cm⁻¹. Wavelength tuning range is typically dependent on a center or nominal wavelength (e.g., different ranges are associated with a wavelength in the short IR, mid-IR, and terahertz), diffraction grating parameters, and external cavity geometry and cavity optics. In some examples, one or both of the first and second mirrors 110, 112 are galvanometer tuning mirrors that allow high-speed wavelength tuning, such as greater than or equal to 1 kHz.

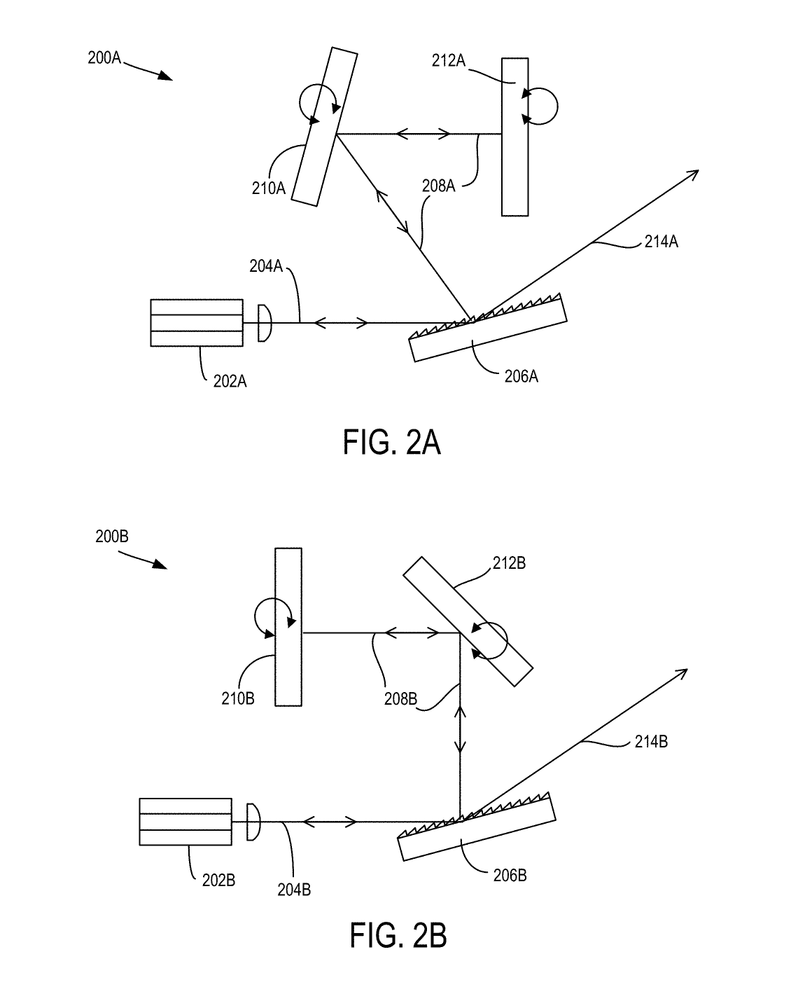

FIGS. 2A-2B show examples of additional external cavity lasers 200A, 200B that are generally distinct from traditional Littman-Metcalf configuration, though can be considered as modified Littman-Metcalf configurations in some examples. The external cavity lasers 200A, 200B include respective laser sources 202A, 202B situated to produce corresponding laser beams 204A, 204B, respective diffraction gratings 206A, 206B situated to diffract the respective laser beams 204A, 204B into first portions forming respective intracavity beams 208A, 208B that are reflected by respective rotatable first mirrors 210A, 210B and respective rotatable second mirrors 212A, 212B and into second portions forming respective output beams 214A, 214B. In the external cavity laser 200A, after reflection by the first mirror 210A, second mirror 212A, and a second reflection by the first mirror 210A, the intracavity beam 208A is diffracted by the diffraction grating 206A to become directed back into the laser source 202A so as to provide feedback and wavelength selection for the laser source 202A. The output beam 214A is directed by the diffraction grating 206A (e.g., based on angle and/or diffraction order selection) so that the output beam 214A does not propagate between the first and second mirrors 210A, 212A. In the external cavity laser 200B, after reflection by the second mirror 212B, the first mirror 210B, and a second reflection by the second mirror 212B, the intracavity beam 208B is diffracted by the diffraction grating 206B (e.g., based on angle and/or diffraction order selection) so that the output beam 214B does not propagate between the first and second mirrors 210B, 210B. In general, the schematics of the external cavity lasers 100, 200A, 200B show optical components and beam propagation paths lying in a common plane of the respective figures. However, other out of plane propagation paths and component positions are possible.

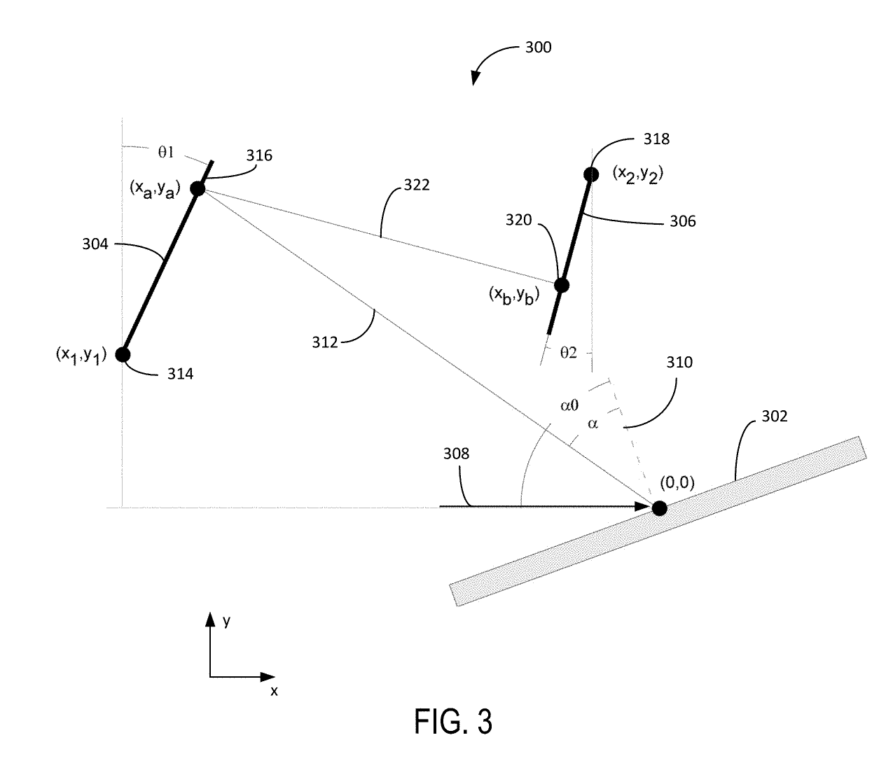

FIG. 3 shows a geometric model of an external cavity laser 300 including angles and positions of a diffraction grating 302 and a first mirror 304 and second mirror 306. A laser source, such as a QCL gain chip, ICL gain chip, laser diode, etc., and associated collimation optics are not shown for clarity, as distance between the laser source and the diffraction grating 302 typically does not change as the first and second mirrors 304, 306 are rotated. A ray 308 from the laser source is incident on the diffraction grating 302 at (x,y)=(0,0). Let α₀ be the incident angle on the diffraction grating 302 with respect to a diffraction grating normal 310 and let α be angle of a diffracted ray 312 with respect to the diffraction grating normal 310. From the diffraction grating equation, we obtain:

$$α = {sin}^{- 1} [ \frac{N}{\tilde{v}} - sin ( {α}_{0} ) ]$$

where N is the grating groove density (grooves/cm) and \tilde{v} is the wavenumber of the light with units of cm⁻¹. Alternatively, \tilde{v}=λ⁻¹, where λ is the wavelength.
A pivot point 314 of the first mirror 304 is defined as (x₁, y₁), and an angle of the first mirror 304 is defined as θ1 with respect to the y-axis. Let (xₐ, yₐ) be the point 316 at which the ray 312 from the diffraction grating 302 intercepts the first mirror 304. A pivot point 318 of the second mirror 306 is defined to be (x₂,y₂) and an angle of the second mirror 306 is defined as θ2 with respect to the y-axis. Let (x_{b}, y_{b}) be the point 320 at which a ray 322 from the first mirror 304 intercepts the second mirror 306. Based on these definitions and geometrical considerations, the following relationships are derived:

$$tan {θ}_{1} = \frac{( {x}_{a} - {x}_{1} )}{( {y}_{a} - {y}_{1} )}$$

$$tan ( {α}_{0} - α ) = - \frac{{y}_{a}}{{x}_{a}}$$

From these equations, the coordinates (xₐ, yₐ) of the ray 312 being received by the first mirror 304 are calculated as:

$$\begin{matrix}{x}_{a} = \frac{{x}_{1} - {y}_{1} tan {θ}_{1}}{1 + tan ( {α}_{0} - α ) \cdot tan {θ}_{1}} & \\ {y}_{a} = - {x}_{a} tan ( {α}_{0} - α ) & \end{matrix}$$

Because the beam is retro-reflected from the second mirror 306:

$$\begin{matrix} {θ}_{2} = 2 {θ}_{1} - ( {α}_{0} - α ) & \\ tan {θ}_{2} = \frac{( {x}_{2} - {x}_{b} )}{( {y}_{2} - {y}_{b} )} & \\ {( {x}_{2} - {x}_{a} )}^{2} + {( {y}_{2} - {y}_{a} )}^{2} = {( {x}_{b} - {x}_{a} )}^{2} + {( {y}_{b} - {y}_{a} )}^{2} + {( {x}_{b} - {x}_{2} )}^{2} + {( {y}_{b} - {y}_{2} )}^{2} & \end{matrix}$$

Using the above equations, the coordinates (x_{b}, y_{b}) of the ray 322 being received by the second mirror 306 are calculated to be:

$$\begin{matrix}{y}_{b} = {y}_{2} + \frac{( {x}_{a} - {x}_{2} ) \cdot tan {θ}_{2} + ( {y}_{a} - {y}_{2} )}{1 + {( tan {θ}_{2} )}^{2}} & \\ {x}_{b} = {x}_{2} + ( {y}_{2} - {y}_{b} ) \cdot tan {θ}_{2} & \end{matrix}$$

The positions of the rays 312, 322 at the first mirror 304 and the second mirror 306 can be calculated given input pivot positions for the first and second mirrors 304, 306, and the angle of the first mirror 304. The angle of second mirror 306 is calculated as determined by a retro-reflection condition for a given specified lasing wavenumber set by the diffraction angle α from the diffraction grating 302.
Alternatively, θ₂, the angle of the second mirror 306, is specified and from this the lasing wavelength is determined according to the retro-reflection condition. In this case:

$$\begin{matrix}α = {θ}_{2} - 2 {θ}_{1} + {α}_{0} & \\ \tilde{v} = \frac{N}{sin ( {α}_{0} ) + sin ( α )} & \end{matrix}$$

Using the equations derived above, the cavity length for a given set of conditions is calculated as:

L=L_{QCL}+L₀+\sqrt{xₐ²+yₐ²+(xₐ−x_{b})²+(yₐ−y_{b})²}

Here, L₀ is the optical pathlength between a front facet of the laser source and the diffraction grating 302 and L_{QCL} is the optical pathlength of the laser source itself (here denoted QCL for a quantum cascade laser example), determined by the product of refractive index and physical device length of the laser source, such as between the front facet and a rear facet.
To assess the ability to tune the cavity length in the proper ratio to the wavelength tuning, consider that a given longitudinal mode satisfies the condition:

$$L = \frac{m λ}{2} = \frac{m}{2 \tilde{v}}$$

where m is an integer.
To change the wavenumber without experiencing a mode-hop to an adjacent longitudinal mode, the quantity \tilde{v}L is preferably kept constant or within a value of ˜±0.5. In addition to the external cavity, the QCL facets define a Fabry-Perot (FP) cavity. Depending on the reflectivity of the front facet and external cavity feedback, the FP cavity associated with the device may define additional FP modes which restrict the laser wavelength of the external cavity laser 300. These FP modes will satisfy the condition:

$${L}_{QCL} = \frac{l λ}{2} = \frac{l}{2 \tilde{v}}$$

where l is an integer.

Having the first mirror 304 and the second mirror 306 in the external cavity laser 300 provides considerable flexibility in cavity tuning of the external cavity laser 300. In some examples, the first mirror 304 may be used to coarsely select wavelength of the external cavity laser based on rotation angle θ1 before directing the beam to the second mirror 306. As the angle of the first mirror 304 is changed, the angle of second mirror 306 is changed in the predetermined relative angle (typically according to a predetermined ratio or slowly varying ratio) that can provide a desired wavelength tuning or scan range. However, there are multiple combinations of the angles of the first mirror 304 and the second mirror 306 which can select the same wavelength of the external cavity laser 300. In some examples, based on the starting positions of the first mirror 304 and the second mirror 306, and the scan range of the first mirror 304, it is possible to scan the cavity length over a range without producing mode-hops or with producing fewer mode hops as compared with other external cavity laser devices, as described hereafter.

In one embodiment, the above equations were used to simulate the tuning behavior of an external cavity quantum cascade laser (ECQCL) with a 2-mirror scan configuration, similar to the configuration shown in FIG. 3. LabVIEW was used for these simulations. Definitions of the inputs and outputs for the simulations are listed in Table 1.

TABLE 1
Description of simulation inputs and outputs

| | Description | Units |
|---|---|---|
| Input | | |
| (x₁, y₁) | Spatial position of pivot point for mirror 1 | cm |
| (x₂, y₂) | Spatial position of pivot point for mirror 2 | cm |
| L_{QCL} | Optical pathlength of QCL chip | cm |
| L₀ | Optical pathlength from QCL front facet | cm |
| | to diffraction grating | |
| N | Diffraction grating groove density | cm⁻¹ |
| α₀ | Incident angle on diffraction grating | degrees |
| θ₁ | Starting angle of mirror 1 | degrees |
| θ₂ | Starting angle of mirror 2 | degrees |
| Output | | |
| ν | Lasing wavenumber | cm⁻¹ |
| L | Total cavity length | cm |

To simulate a wavelength scan of the ECQCL, the angle of a first mirror, e.g., the first mirror 304 is scanned across a user-defined range of angles: θ₁(i)=δ₁+i·Δθ, where i is an integer. The scan for a second mirror, e.g., the second mirror 306 is synchronized with the first, but with a scale factor k applied: θ₂(i)=θ₂+k·l·Δθ. For each step i the lasing wavenumber and total cavity length are calculated, and then the external cavity mode index calculated via m=round (2·\tilde{v}·L) to find the nearest integer mode index. As the first and second mirrors are scanned and the wavenumber changed, a change in mode index indicates a mode-hop. Simulations were run using parameters approximating an ECQCL configuration similar to the one used in the experimental results presented below. Table 2 shows the parameters used.

TABLE 2
Values of parameters used in simulations

| Input | Value | Units |
|---|---|---|
| (x₁, y₁) | (−1, 2.5) | cm |
| (x₂, y₂) | (5, 0.5) | cm |
| L_{QCL} | 0.7 | cm |
| L₀ | 5 | cm |
| N | 1500 | cm⁻¹ |
| α₀ | 65 | degrees |
| θ₁ | 50 | degrees |
| θ₂ | 28 | degrees |

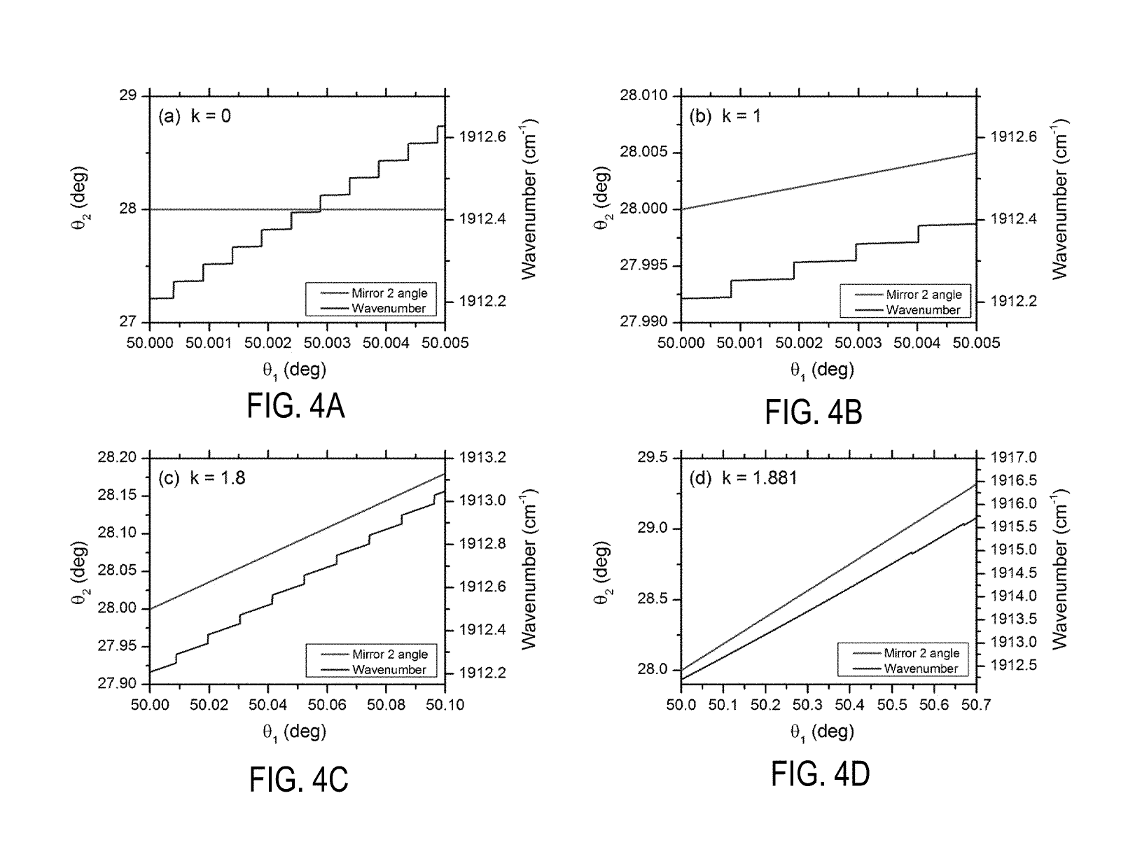

For scans of first mirror and the second mirror, simulated results are shown in FIGS. 4A-4D. Different values of the scale parameter k are used to illustrate different examples. In FIG. 4A (k=0), the angle of the second mirror is held constant, which simulates the conditions of a standard Littman-Metcalf cavity with one tuning mirror. As the angle of the first mirror is changed, mode-hops are shown with a wavenumber spacing of 0.04 cm⁻¹, corresponding to the mode spacing of the external cavity of total length 12.5 cm. FIG. 4B (k=1) shows the output wavenumber when the second mirror is rotated with the same angular displacement as the first mirror. In this example, the regions of stability without mode-hops are extended; however, there is relatively small range of smooth wavenumber tuning between mode-hops. FIG. 4C (k=1.8) shows simulation results that approaches a reduced or mode-hop free tuning behavior. In this example, the regions of stability show linear tuning and the mode-hops are reduced in amplitude. FIG. 4D (k=1.881) shows the near-optimum ratio of rotation between the first mirror and the second mirror to provide mode-hop free tuning. The region of stability is increased to 2.7 cm⁻¹ before a first mode-hop occurs. Such a tuning range would be sufficient for many high-resolution spectroscopy experiments and is similar to the tuning range achieved via current-tuning of a distributed feedback (DFB)-QCL. However, the ECQCL has the advantage that the center tuning wavelength can be adjusted by ˜10%, in contrast to the DFB-QCL which has a fixed center wavelength.

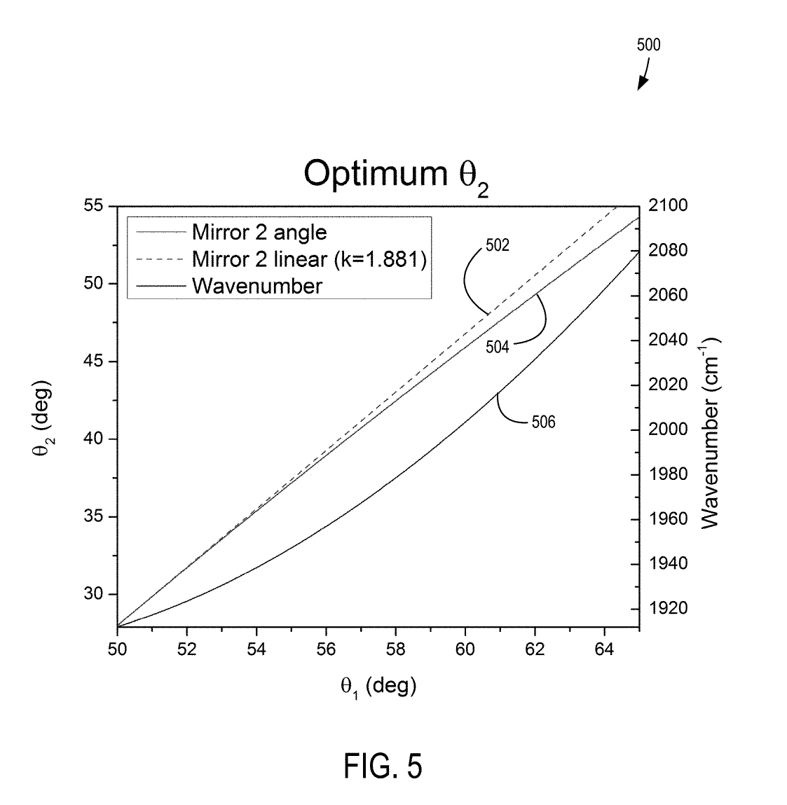

The results of the simulations in FIGS. 4A-4D used a linear relationship between the angles of the first mirror and the second mirror. Inversion of the equations shown above can provide an alternative functional relationship between the mirror angles to extend the mode-hop-free tuning range even further. FIG. 5 shows a graph 500 of the results of a numerical simulation that was performed in which the angle of the second mirror was optimized by searching over a range of values to keep the mode index constant as the first mirror was rotated over a large range. The dashed line 502 shows the angle of a second mirror for a linear scan with scale factor k=1.881. The solid line 504 is the result of an optimization to find the angle of a second mirror angle that maintains a constant mode index as the first mirror is scanned. A variation of wavenumber is shown with solid line 506 that varies according to the variation of the first mirror angle. The simulation that the mode-hop-free tuning range can be extended to >150 cm⁻¹ via optimized tuning of the second mirror with respect to the first mirror. In some examples, tuning range of the external cavity is only limited by spatial displacement of the beams off the first mirror and/or second mirror. In further examples, tuning range is only limited by the effects of device FP modes, as discussed hereafter.

Two laboratory prototypes were constructed to demonstrate use of the disclosed technology to produce continuous wavelength variations, or scans, without mode-hops in ECQCLs. The first system, denoted ECQCL1, used a QCL chip designed to emit at a center wavelength of 5.2 μm (1920 cm⁻¹). A diffraction grating with 150 grooves/mm was used to disperse the wavelengths. Two galvanometer-mounted tuning mirrors were used to provide wavelength tuning of the ECQCL1. For ECQCL1, the arrangement of mirrors was similar to that shown in FIG. 1.

As described above, by synchronous adjustments of both mirrors, the ECQCL wavelength could be scanned continuously without experiencing mode-hops. In addition to the two mirrors, the QCL current was adjusted synchronously with the mirror. The QCL current modulation was used to reduce or prevent mode-hops due to the Fabry-Perot (FP) cavity and associated FP modes formed by the end facets of the QCL chip. Although the front QCL facet was antireflection-coated, the residual reflectivity was sufficient to be associated with mode-hops in the output of the external cavity laser on the FP modes, spaced by ˜0.6 cm⁻¹. Changing the current applied to the QCL can change the effective chip length via thermal heating. As a result, the wavelengths of the FP modes formed by this cavity can be moved in coordination with the wavelength variation of the external cavity laser produced with the rotating mirrors. In one of the prototypes, the drive signals to the two galvanometer-mounted mirrors and the QCL current were supplied by analog output channels from a data acquisition board. The galvanometer control boards moved the galvanometer mirrors with a linear or approximately linear relationship between drive voltage and output angle. For the galvanometers used, the scale factor was determined to be ˜3°/V.

A LabVIEW program was constructed to drive the galvanometer mirrors and provide the current modulation to the QCL, as well as collect data from the infrared photodetector. The control signals to the mirrors and the current controller were determined as follows:

V₁=A₁ sin(2πft)+O₁

V₂=k·A₁ sin(2πft)+O₂

I=c·A₁ sin(2πft+ϕ)+I₀

In these formulas, V₁ is the sinusoidal voltage applied to mirror 1 with amplitude A₁, frequency f, and offset O₁. V₂ is the sinusoidal voltage applied to mirror 2, with amplitude k·A₁, frequency f, and offset O₂. I is the sinusoidal current applied to the QCL, with amplitude c·A₁, frequency f, phase ϕ, and offset I₀. The sinusoidal modulation could be replaced with any function if desired; however, the sine function is useful and can be optimal for high speed modulation of the galvanometers. The modulation of the second mirror is derived from the same modulation as the first mirror, but with a different amplitude and offset. The modulation of the current is also derived from the same modulation as the first mirror, with a different amplitude and offset, and also with an adjustable phase. The phase term can be associated with different modulation bandwidths of the galvanometer controllers and the current controller or other time delays, resulting in a frequency-dependent phase-shift between the galvanometer and current signals.

TABLE 3
Scan parameters used in experiments

| Parameter | Value |
|---|---|
| f | 500 Hz |
| A₁ | 0.07 V |
| o₁ | 0.104 V |
| k | 1.911 |
| o₂ | 0.398 |
| c | −9000 mA/V |
| φ | −120° |
| I₀ | −400 mA |

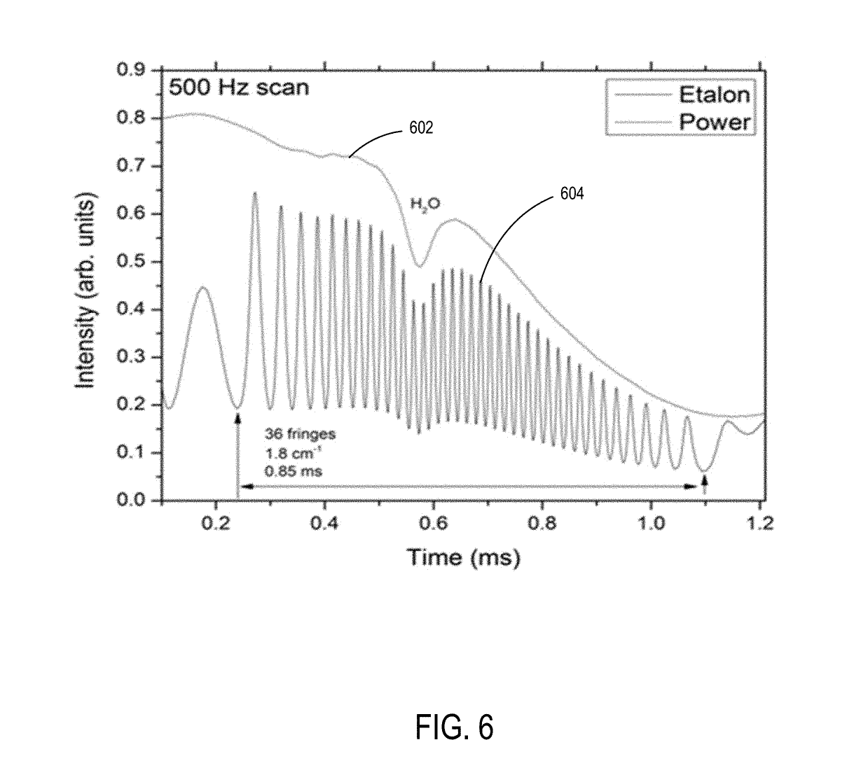

An example of continuous wavelength scanning results is shown in FIG. 6 using the parameters in Table 3. In this example, first and second tuning mirrors were rotated according to a 500 Hz sine wave modulation, which resulted in an effective wavelength tuning scan rate of 1 kHz, based on both the forward and backward scans of the sine wave across the wavelength tuning range. Power and etalon signal traces 602, 604 show the measured ECQCL output power, and transmission through a solid Ge etalon, respectively, as a function of time for one half-period of the 500 Hz sinusoidal modulation. Smooth signals are observed without discontinuities in the power or etalon signal traces 602, 604, demonstrating a mode-hop free scan. For the 500 Hz scan, 36 etalon fringes were recorded. Using the known 0.05 cm⁻¹ fringe spacing of the etalon, the tuning range is determined to be 1.8 cm⁻¹. The corresponding time to scan over this range was 0.85 ms. Also visible in FIG. 6 is an absorption line most likely due to atmospheric water vapor. There are multiple water vapor absorption lines in the 1905 cm⁻¹ wavenumber region where ECQCL1 was operating.

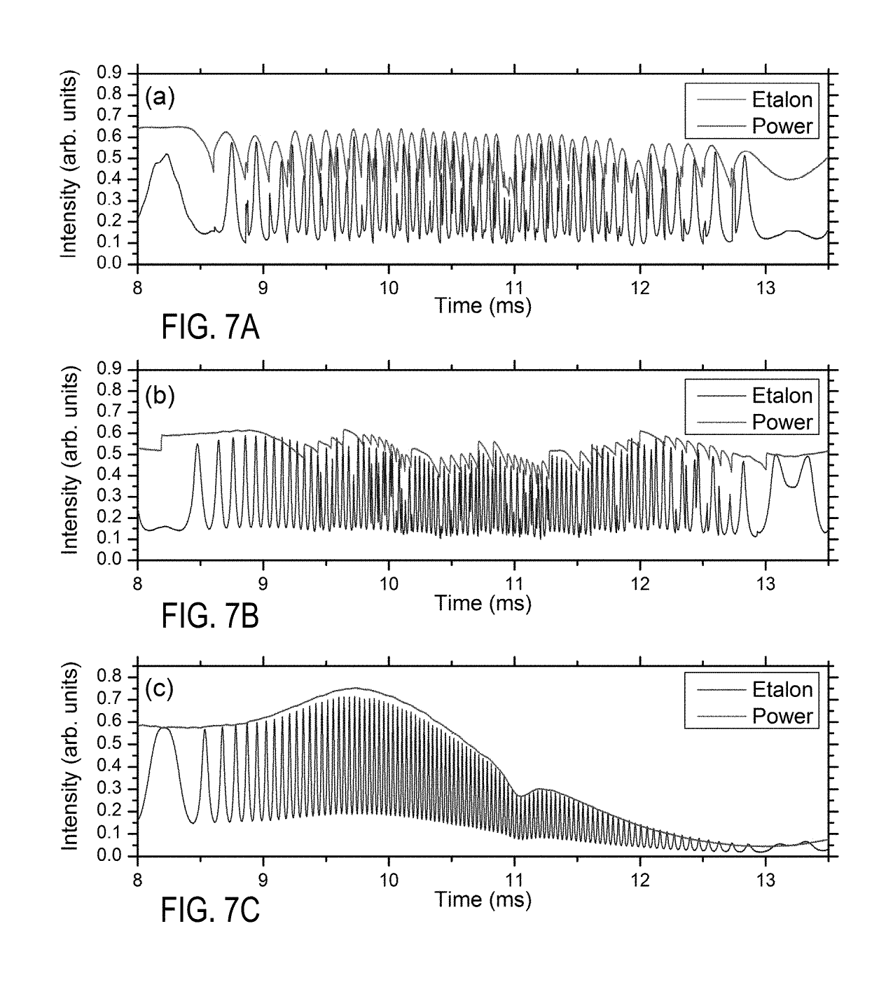

FIGS. 7A-7C show various examples of wavelength tuning behavior for the ECQCL1 for various scan parameters. In these examples, the wavelength tuning elements were scanned using a 100 Hz sinusoidal modulation. A Ge etalon was used with a 5.08206 cm length and n=4.015 (at 5.25 μm wavelength) giving a mode spacing of 0.0245 cm⁻¹. FIG. 7A shows tuning performance with only a first mirror being scanned, similar to a conventional Littman-Metcalf cavity configuration, and which exhibits a large number of mode-hops. FIG. 7B shows tuning performance with both a first mirror and a second mirror being rotated to prevent or reduce external cavity mode-hops; however, the current to the QCL device is not varied or not varied in coordination with the rotations of the first and second mirrors. The scan results show improved performance with fewer mode hops than the results shown in FIG. 7A, but is not optimal.

FIG. 7C shows a continuous scan results with the first mirror, second mirror, and device current are varied to reduce or prevent mode-hops. The tuning range associated with the scan results in FIG. 7C was 2.3 cm⁻¹ at a center wavenumber of 1907.70 cm⁻¹. Such a tuning range is similar to tuning ranges in DFB-QCLs with current tuning.

Using ECQCL1, it was possible to achieve continuous scans of 2-3 cm⁻¹ range at multiple center wavenumbers throughout the overall tuning range of the ECQCL1. The range of center wavelengths spanned 1846 cm⁻¹-1958 cm⁻¹, or a total range of 112 cm⁻¹. It is extremely significant to achieve this span of center wavelengths using a single QCL device. To achieve this same range of center wavelengths with DFB-QCLs would require 5-10 different QCL devices (depending on how far each one could be tuned via temperature). In addition, the scans were achieved at a high speed (200 Hz effective scan rate in this case).

A second ECQCL system, denoted ECQCL2, was constructed to demonstrate wavelength tuning operation in a different wavelength region. ECQCL2 used a QCL gain chip designed for operation near 4.6 am wavelength and a diffraction grating with 150 grooves/mm. For ECQCL2, an arrangement of first and second mirrors was similar to that shown in FIG. 2. A coarse tuning range of ECQCL2 was measured to be 2070-2275 cm⁻¹. The first and second mirror tuning elements were scanned using sinusoidal modulation at 500 Hz. Mode-hop-free continuous scans were demonstrated for various center wavenumbers including and between 2070 cm⁻¹ and 2263 cm⁻¹. Scan ranges of 1 cm⁻¹ were demonstrated at both center wavelengths. The results with ECQCL2 demonstrate that examples of the disclosed technology can include lasers operating at various central wavelengths.

Typical fine tuning of external cavity diode lasers uses a piezoelectric transducer to adjust an external cavity length. In some examples herein, a fine tuning range of 0.16% of the center wavenumber was demonstrated without using a piezoelectric transducer and corresponds to a fractional change in cavity length of 0.16%. For a typical cavity length of 10 cm such a fractional change would require a linear motion of 160 μm. This large range of motion is extremely challenging to achieve with piezoelectric transducers, especially at high speed and with compact size elements. The two-mirror approach to adjusting the cavity length solves these problems.

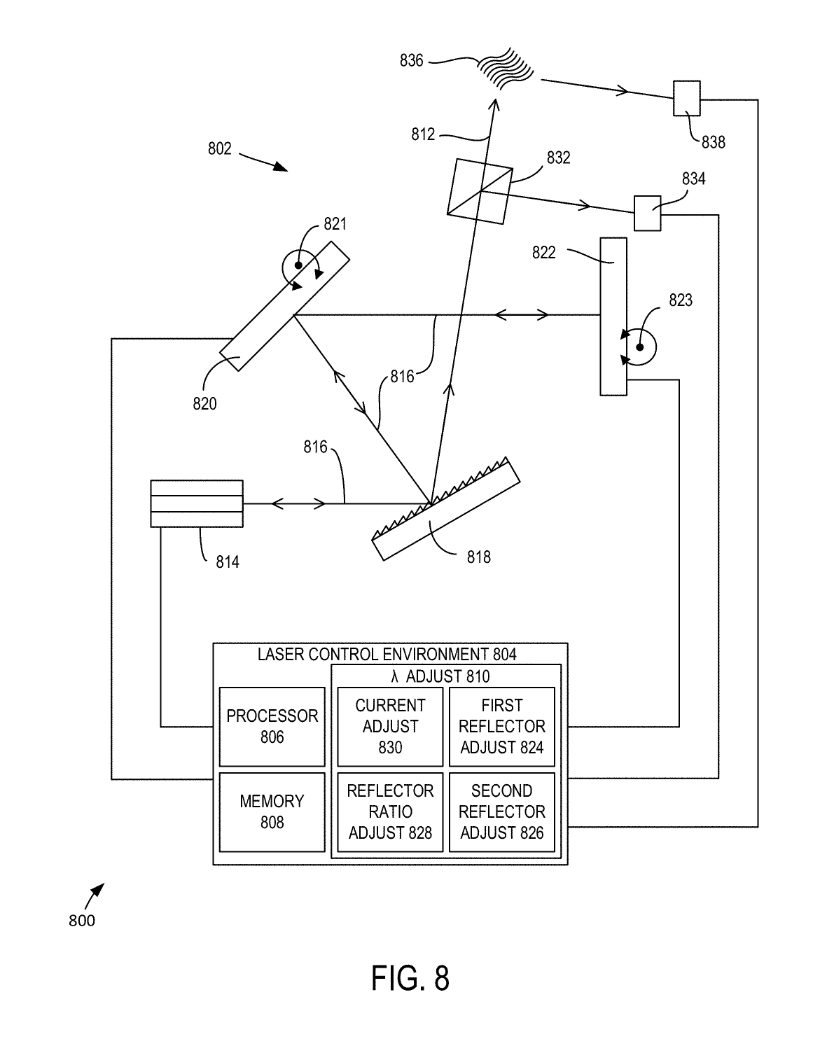

FIG. 8 shows a system 800 that includes an external cavity laser 802 coupled to a laser control environment 804 that can include one or more computing devices including a processor 806 and memory 808 coupled to the processor 806. The control environment 804 includes a wavelength adjust control module 810 situated to control a wavelength of an output beam 812 that is produced by the external cavity laser 802. The external cavity laser 802 includes a laser source 814, such as a QCL or other semiconductor laser device, situated to produce an intracavity laser beam 816 that is directed to a diffraction grating 818 typically situated in a fixed relation and distance to the laser source 814. The intracavity laser beam 816 is diffracted by the diffraction grating 818 and a selected diffraction order propagates to form the output beam 812 and a different diffraction order propagates to a first reflector 820 that is situated to rotate about an axis 821. The intracavity laser beam 816 is directed to a second reflector 822 that is situated to rotate about a separate axis 823 and to reflect the intracavity laser beam 816 to return to the first reflector 820 along a common path for a selected wavelength that satisfies a retroreflection condition. The intracavity laser beam 816 is directed from the first reflector 820 to the diffraction grating 818 and back to the laser source 814. The returning light of the intracavity laser beam 816 selects a lasing frequency of the laser source 814. The first reflector 820 and the second reflector 822 are controllably coupled to a first reflector adjust 824 and a second reflector adjust 826 of the wavelength adjust control module 810. In typical examples, the first reflector adjust 824 controls a rotation (e.g., angular position, angular speed, etc.) of the first reflector 820 about the axis 821 based on a selected wavelength of the output beam 812, and the second reflector adjust 826 controls a rotation the second reflector 822 about the axis 823 based on the selected wavelength of the output beam 812.

In some examples, the rotations of the first reflector 820 and the second reflector 822 are synchronized to rotate separately according to a fixed ratio that is typically greater than 1:1. In some examples, synchronized rotations of the first reflector 820 and the second reflector 822 produce a selected variation of the external cavity length and a wavelength-selective diffraction angle of the intracavity laser beam 816 at the diffraction grating 818. In further examples, a shift in the spectral selectivity for the laser source 814 based on the variation of the diffraction angle of the diffraction grating 818 is accompanied by a shift of a longitudinal mode spectrum of the external cavity laser 802 that is associated with the variation of the length of the external cavity laser 802. In some examples, the shifts of the spectral selectivity and the longitudinal mode spectrum are synchronized so as to reduce or eliminate mode hopping between longitudinal modes of the external cavity over one or more predetermined ranges of wavelength or wavenumber of the output beam 812. In some examples, a ratio of rotations of the first reflector 820 and the second reflector 822 is variable, e.g., with a reflector ratio adjust 828, and the variation can be used to extend a range of wavelength variation of the output beam 812 that is free of mode hops between longitudinal modes of the external cavity. In additional embodiments, the wavelength adjust module 810 includes a current adjust 830 that varies a current supplied to the laser source 814 to shift or vary a longitudinal mode spectrum of the Fabry-Perot modes of the laser source 814. In further embodiments, a beam pickoff 832 such as a beam splitter directs a portion of the output beam 812 to an optical detector 834 such as a photodiode, etalon, etc. The optical detector 834 can be coupled to the laser control environment 804 so that one or more control variables of the external laser cavity 802, including the rotations of the first reflector 820, second reflector 822, and current modulation applied to the laser source 814, can be corrected to adjust wavelength of the output beam 812 or reduce mode hopping. In some examples, the first reflector 820 and the second reflector 822 are galvanometer scan mirrors, and can be scanned at relatively fast frequencies. In some examples, rotational frequencies of the galvanometer scan mirrors can include 1 Hz or greater, 10 Hz, or greater, 100 Hz or greater, 500 Hz or greater, 1 kHz or greater, or faster. Wavelength scan ranges can depend on the gain bandwidth of the laser source and center wavelength or wavenumber, and can include 0.1 cm⁻¹ or greater, 0.2 cm⁻¹ or greater, 0.5 cm⁻¹ or greater, 1 cm⁻¹ or greater, 2 cm⁻¹ or greater, 5 cm⁻¹ or greater, or larger, for various laser gain media operating in the wavelength range from UV to far infrared or terahertz (e.g., 100 nm to 1000 am). In some examples, the output beam 812 is directed to a target 836 of interest, such as a solid, liquid, or gas phase material. A detector 838, such as an optical detector, can be coupled to the target 836 so as to produce a detection signal that is coupled to the laser control environment 804 and that is associated with wavelength characteristics of light emitted by the target 836.

The wavelength adjust control module 810 can include software or firmware instructions carried out by a digital computer. For example, any of the disclosed wavelength and/or mode-hop control techniques can be performed by a computer or other computing hardware (e.g., an ASIC, FPGA, PLC, CPLD, etc.) that is part of an external cavity laser control system. The laser control environment 804 can be connected to or otherwise in communication with the first reflector 820, second reflector 822, and laser source 814 and programmed or configured to adjust diffraction angle, external cavity length, and longitudinal mode spectra based on reflector angles and device currents, and also to control the various adjustments based on open loop or closed-loop feedback control techniques. The computer can be a computer system comprising one or more of the processors 806 (processing devices) and memory 808, including tangible, non-transitory computer-readable media (e.g., one or more optical media discs, volatile memory devices (such as DRAM or SRAM), or nonvolatile memory or storage devices (such as hard drives, NVRAM, and solid state drives (e.g., Flash drives)). The one or more processors 806 can execute computer-executable instructions stored on one or more of the tangible, non-transitory computer-readable media, and thereby perform any of the disclosed techniques. For instance, software for performing any of the disclosed embodiments can be stored on the one or more volatile, non-transitory computer-readable media as computer-executable instructions, which when executed by the one or more processors, cause the one or more processors to perform any of the disclosed external cavity wavelength variation techniques. The results of the computations and detected wavelength characteristics of the target 836 can be stored (e.g., in a suitable data structure) in the one or more tangible, non-transitory computer-readable storage media and/or can also be output to a user, for example, by displaying, on a display device, wavelength, scan angle, device current, etc., with a graphical user interface.

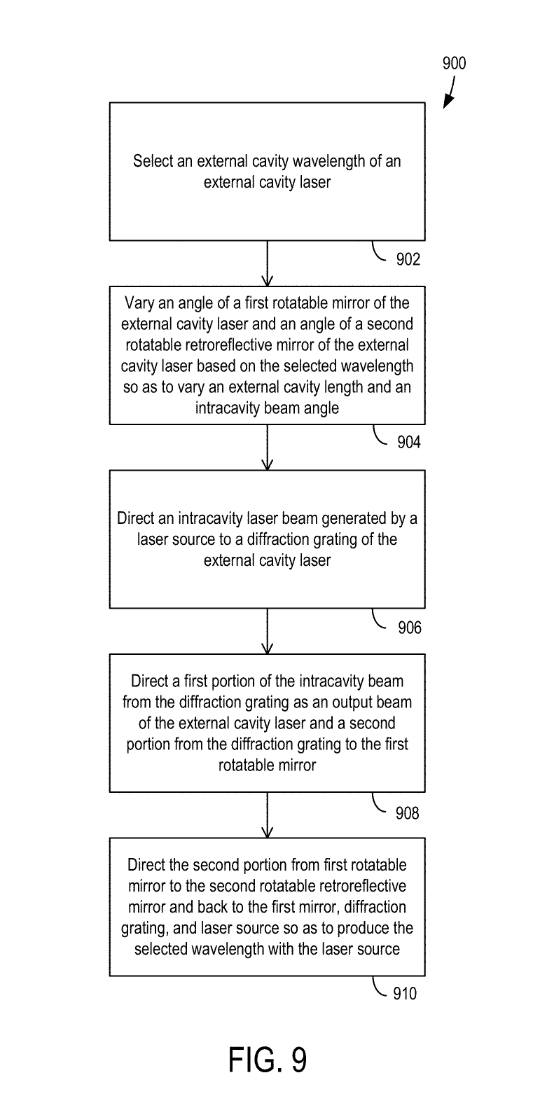

FIG. 9 is an example method 900 of varying a wavelength of an external cavity laser. At 902, a wavelength of an output beam of the external cavity wavelength is selected. In some examples, a single wavelength or a plurality of single wavelengths can be selected. In further examples, wavelength selection includes scanning the wavelength across one or more predetermined ranges of wavelength. At 904, an angle of a first rotatable mirror situated to direct an intracavity beam of the external cavity to a second rotatable mirror situated to direct the intracavity beam to the first rotatable mirror, and an angle of the second rotatable mirror, are varied based on the wavelength selected at 902. The variation of the angles of the first rotatable mirror and the second rotatable mirror produce a variation of an intracavity beam angle between the first rotatable mirror and a diffraction grating and also a variation of a length of the external cavity of the external cavity laser. At 906, an intracavity beam generated by a laser source, such as a quantum cascade laser, diode laser, or other semiconductor gain chip, is directed to the diffraction grating. At 908, a first portion of the intracavity beam is directed from the diffraction grating (e.g., a predetermined diffraction order) so as to form an output beam of the external cavity laser. A second portion of the intracavity beam (e.g., a different predetermined diffraction order) is directed to the first rotatable mirror. At 910, the second portion is directed from the first rotatable mirror to the second rotatable mirror, is directed back to the first rotatable mirror, diffraction grating, and laser source, so as that the laser source produces the selected wavelength.

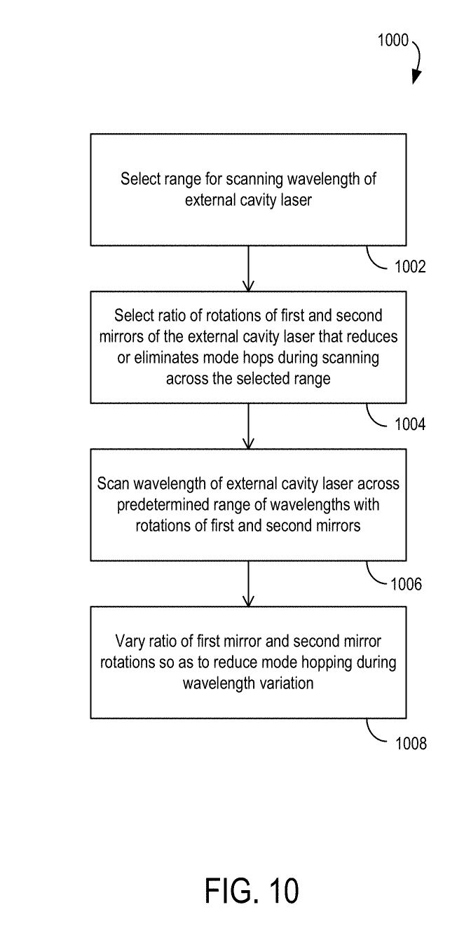

FIG. 10 is an example method 1000 of scanning a wavelength of an external cavity laser using a pair of rotatable scan mirrors. At 1002, a wavelength scanning range is selected for the external cavity laser. In some examples, the wavelength range is limited by an allowed lasing wavelength of a laser source of the external cavity laser. In further examples, the wavelength range can be determined by the surface length and/or angular freedom of the rotatable scan mirrors, e.g., before an intracavity beam misses the rotatable scan mirrors. At 1004, a ratio of angular rotation is selected for the first and second rotatable scan mirrors. In representative examples, the ratio is selected that reduces or eliminates mode hops during scanning across the entire selected wavelength scanning range or less than the entire selected wavelength scanning range. At 1006, the wavelength of the external cavity laser is scanned across the selected wavelength scanning range based on the rotations of the first and second mirrors. In some examples, at 1008, the ratio of angular rotation of the first and second scan mirrors is varied in relation to the rotation angle of one or both of the first and second scan mirrors to further reduce mode-hopping over an extended wavelength scan range.

In some examples, wavelength tuning of the external cavity laser can be used for applications in high-resolution infrared spectroscopy and gas-sensing.

Having described and illustrated the principles of the disclosed technology with reference to the illustrated embodiments, it will be recognized that the illustrated embodiments can be modified in arrangement and detail without departing from such principles. For instance, elements of the illustrated embodiments shown in software may be implemented in hardware and vice-versa. Also, the technologies from any example can be combined with the technologies described in any one or more of the other examples. It will be appreciated that procedures and functions such as those described with reference to the illustrated examples can be implemented in a single hardware or software module, or separate modules can be provided. The particular arrangements above are provided for convenient illustration, and other arrangements can be used.

In view of the many possible embodiments to which the principles of the disclosed technology may be applied, it should be recognized that the illustrated embodiments are only representative examples and should not be taken as limiting the scope of the disclosure. Alternatives specifically addressed in these sections are merely exemplary and do not constitute all possible alternatives to the embodiments described herein. For instance, various components of systems described herein may be combined in function and use. I therefore claim all that comes within the scope of the appended claims.

I claim:

1. An apparatus, comprising:
a first reflector rotatable about a first axis and situated to receive an intracavity laser beam of an external cavity laser from a diffraction grating and to direct the intracavity laser beam along a first direction; and
a second reflector rotatable about a second axis and situated to retro-reflect the intracavity laser beam received from the first reflector back to the first reflector and to the diffraction grating.

2. The apparatus of claim 1, wherein the first reflector and second reflector are situated to rotate separately so as to vary an angle of the intracavity laser beam received from the diffraction grating that corresponds to a variation of a lasing wavelength of the external cavity laser over a predetermined range and so as to vary a cavity length of the external cavity laser.

3. The apparatus of claim 2, wherein a variation of the angle and a variation of the cavity length based on rotations of the first reflector and the second reflector correspond to the variation in the lasing wavelength of the external cavity laser without mode hopping over the predetermined range.

4. The apparatus of claim 2, wherein the predetermined range is larger than a longitudinal mode spacing of the external cavity laser.

5. The apparatus of claim 3, wherein the predetermined range corresponds to at least 0.04% of a center wavenumber of the intracavity laser beam.

6. The apparatus of claim 2, wherein a variation of the cavity length and a variation of the lasing wavelength based on rotations of the first reflector and the second reflector correspond to a product of external cavity length and center wavenumber that is constant or within ±0.01, ±0.1, ±0.25, or ±0.5 of a selected value over the predetermined range.

7. The apparatus of claim 2, wherein the first reflector and second reflector are situated to rotate according to a predetermined ratio associated with a mode hop reduction.

8. The apparatus of claim 7, wherein the predetermined ratio is variable with respect to an angle position of the first reflector or the second reflector.

9. The apparatus of claim 1, further comprising the diffraction grating situated to receive the intracavity laser beam from a laser source of the external cavity laser and to direct the intracavity laser beam to the first reflector and to direct an output beam in an output beam direction.

10. The apparatus of claim 1, further comprising a laser source situated to produce the intracavity laser beam and to direct the intracavity laser beam to the diffraction grating.

11. The apparatus of claim 10, further comprising one or more collimation optics situated to receive the intracavity laser beam from the laser source and to direct the intracavity laser beam to the diffraction grating as a collimated beam.

12. The apparatus of claim 1, further comprising a controller coupled to the first reflector and second reflector and situated to control a rotation of the first reflector about the first axis and a rotation of the second reflector about the second axis.

13. The apparatus of claim 12, further comprising a detector optically coupled to the intracavity laser beam or an output beam of the external cavity laser formed by the diffraction grating so as to detect an optical characteristic, wherein the controller is situated to control the rotation of the first reflector and second reflector based on the detected optical characteristic.

14. The apparatus of claim 1, wherein the first axis and second axis are parallel.

15. The apparatus of claim 10, wherein the laser source is a quantum cascade laser, interband cascade laser, or diode laser.

16. The apparatus of claim 10, wherein the laser source and the diffraction grating are situated in a fixed relationship relative to the first axis and the second axis.

17. The apparatus of claim 1, wherein the first reflector and the second reflector are galvanometer scan mirrors.

18. A system, comprising:
a plurality of reflectors of an external cavity laser, each situated to rotate about respective axes in relation to a diffraction grating and laser source situated in a fixed relation to each other;
at least one processor; and
one or more computer-readable storage media including stored instructions that, responsive to execution by the at least one processor, cause the system to rotate the plurality of reflectors so as to vary an external cavity length and an external cavity output beam wavelength.

19. A method, comprising:
directing an intracavity laser beam produced by a laser source to a diffraction grating;
directing a first portion of the intracavity laser beam received by the diffraction grating along an output direction so as to form an output beam of an external cavity laser; and
directing a second portion of the intracavity laser beam received by the diffraction grating to a first reflector rotatable about a first axis and to a second reflector rotatable about a second axis so as to retro-direct the second portion back to the first reflector, diffraction grating, and laser source; and
wherein the first reflector and second reflector are situated to independently rotate about respective axes so as to vary a wavelength of the output beam.

20. The method of claim 19, wherein the first reflector and second reflector are situated to rotate about the respective axes so as to vary the wavelength of the output beam and a length of the external cavity.

21. The method of claim 20, wherein variations of the wavelength of the output beam and the length of the external cavity based on rotations about the respective axes corresponds to a mode-hop free variation of the wavelength across a predetermined wavelength range.

22. A method, comprising:
selecting an external cavity output beam wavelength of an external cavity laser that includes a diffraction grating and a laser source situated in a fixed relation to each other; and
rotating an intracavity first reflector and an intracavity second reflector so as to vary a wavelength of the output beam and a length of the external cavity of the external cavity laser.

23. The method of claim 22, wherein variations of the wavelength and the length based on the rotations corresponds to a mode-hop free variation of the wavelength over a predetermined range.
